(19) United States
(12) Patent Application Publication
(10) Pub. No.: US 2014/0370433 A1
(43) Pub. Date: Dec. 18, 2014

(54) POLYMERIZED TONER AND A METHOD FOR PREPARING THE SAME

(71) Applicant: LG CHEM, LTD., Seoul (KR)

(72) Inventors: Wook Jang, Daejeon (KR); Chang-Soon Lee, Daejeon (KR); Joo-Yong Park, Daejeon (KR); Woo-Cheul Jung, Ulsan (KR)

(73) Assignee: LG CHEM, LTD., Seoul (KR)

(21) Appl. No.: 14/368,270

(22) PCT Filed: Dec. 5, 2012
(86) PCT No.: PCT/KR2012/010476

§ 371 Date: Jun. 23, 2014

(30) Foreign Application Priority Data
Dec. 23, 2011 (KR) 10-2011-0141416
Dec. 5, 2012 (KR) 10-2012-0140222

(51) Int. Cl. G03F 7/038

(52) U.S. Cl. CPC G03F 7/0388
USPC 430/108.11; 430/109.1; 430/109.3; 430/108.8; 430/108.4; 430/108.2; 430/108.6; 430/108.3; 430/108.23

(57) ABSTRACT

This disclosure relates to a polymerized toner prepared by suspension polymerization. Particularly, this disclosure relates to a polymerized toner that comprises a binder resin, and a pigment, a charge control agent, and wax, which are dispersed in the binder resin, and maintains peak molecular weight (Mn) of the binder resin, the ratio of number average molecular weight/peak molecular weight (Mn/Mp), and gel content (Gel %), and thereby, can realize high glossiness and excellent off set property when printing, and a method for preparing the same.

### TECHNICAL FIELD

The present invention relates to a polymerized toner and a method for preparing the same. More particularly, the present invention relates to a polymerized toner that may realize high glossiness and excellent off set property, and thus, exhibit very excellent performance in the application field such as development of electronic photographs, and the like.

### BACKGROUND ART

A toner refers to a paint that is used for the development of electronic photographs, an electrostatic printer, a copier, and the like, and can be transferred and fixed to an article to form desired patterns. Recently, as documentation using a computer is generalized, demands for an image forming apparatus such as a printer are rapidly increasing, and thereby, the amount of toner consumed is also increasing.

In general, a method for preparing a toner includes a preparation method by pulverization and a preparation method by polymerization. In the preparation method by pulverization, which is most widely known, resin and pigment are introduced together through a melt-mixing process, they are melt-mixed or extruded, and then, pulverized and classified to prepare toner particles. However, since toner particles prepared by this process have very irregular shapes such as wide particle diameter distribution, sharp edges, and the like, they have problems in that chargability or flowability is not good.

In order to solve these problems, a method for preparing spherical toner particles by a polymerization method has been suggested. As the preparation method of toner by polymerization, an emulsion polymerization method (aggregation method) and a suspension polymerization method are known, but the emulsion polymerization method is difficult to control particle size distribution, and has a problem in terms of quality reproducibility of prepared toner, and thus, a preparation method of toner by suspension method is more favored.

In the suspension polymerization method, monomers for a binder resin, and various additives such as a pigment, a pigment stabilizer, wax, a charge control agent, an initiator, and the like are uniformly dispersed to prepare a monomer mixture, and the mixture is dispersed in an aqueous dispersion in the form of fine droplets, and then, a polymerization reaction is conducted to prepare a polymerized toner in the form of particle appropriate for toner.

However, toner particles prepared by suspension polymerization comprises binder resin having high molecular weight because monomers for a binder resin are polymerized, and due to the binder resin having high molecular weight, glossiness of printed products is lowered. In order to solve the problem, a method of realizing high glossiness in printed products by adding a molecular weight control agent together with various additives such as wax or a charge control agent, and the like has been suggested, but according to the method, the molecular weight of a binder resin is decreased and thus off set property is lowered.

Accordingly, there is a need for the development of a polymerized toner that may simultaneously realize high glossiness and excellent off set property even when a toner is prepared by suspension polymerization.

### DISCLOSURE

### Technical Problem

It is an object of the present invention to provide a polymerized toner that may exhibit very excellent printing performances of high glossiness and excellent off set property in the application field such as development of electronic photographs and the like, and a method for preparing the same.

### Technical Solution

The present invention provides a polymerized toner comprising a binder resin, and a pigment, a charge control agent, wax, which are dispersed in the binder resin, wherein the binder resin has peak molecular weight (Mp) of 10,000 to 50,000, the ratio of number average molecular weight (Mn) to peak molecular weight (Mp) is 0.8 to 1.5, and the gel content (Gel %) measured by a soxhlet method is 5% to 20%.

The present invention also provides a method for preparing the polymerized toner comprising forming an aqueous dispersion comprising a dispersant; forming a monomer mixture comprising monomers for a binder resin, a pigment, a charge control agent, wax, a cross linking agent and a molecular weight control agent; and adding the monomer mixture to the aqueous dispersion to form toner particles through suspension polymerization.

Hereinafter, a polymerized toner and a method for preparing the same according to specific embodiments of the invention will be explained in detail. However, these are presented as one example of the invention, the right scope of the invention is not limited thereto, and it is obvious to one of ordinary knowledge in the art that various modifications may be made thereto within the right scope of the invention.

As used herein, unless otherwise described, “comprising” or “containing” refers to include a certain constitutional element (or constitutional component) without specific limitation, and it cannot be interpreted to exclude the addition of other constitutional elements (or constitutional components).

According to one embodiment of the invention, there is provided a polymerized toner comprising a binder resin, and a pigment; a charge control agent, and wax, which are dispersed in the binder resin. In the polymerized toner, the binder resin may have peak molecular weight (Mp) of 10,000 to 50,000, the ratio (Mn/Mp) of number average molecular weight (Mn) to the peak molecular weight (Mp) may be 0.8 to 1.5, and the gel content (Gel %) measured by a soxhlet method may be 5% to 20%.

And, the binder resin may have number average molecular weight (Mn) of 10,000 to 50,000, and weight average molecular weight (Mw) of 50,000 to 120,000.

The inventors confirmed that if the peak molecular weight (Mp), the ratio of number average molecular weight/peak molecular weight (Mn/Mp), and the gel content (Gel %) of a binder resin in a polymerized toner are maintained within specific ranges, the polymerized toner may improve glossiness and realize excellent off set property when applied for printing. Thus, the polymerized toner of the present invention may be applied in the application field such as development of electronic photographs and the like, which requires realization of uniform image, and printed products having excellent qualities of high resolution and color realization degree may be obtained using the same.

Particularly, when applied for printing, a toner is transferred from a drum to a paper in a developing machine, and the transferred toner is fixed on a paper by heat and pressure while passing through a fixing roll. At this time, if the molecular weight of a binder resin constituting the toner is low, the resin may be sufficiently molten and lowering of glossiness due to scattered reflection may be decreased, but so called off set phenomenon whereby a toner is fused to a fixing roll may occur. To the contrary, if the molecular weight of a binder resin constituting a toner is high, the resin may not be sufficiently molten and glossiness may be lowered due to scattered reflection by non-molten toner particles. Thus, the molecular weight of a binder resin constituting a polymerized toner should be controlled within optimum range so as to prepare a toner that has excellent glossiness and good off set property, i.e., does not generate off set phenomenon.

As confirmed by experimental examples described below, the peak molecular weight (Mp), number average molecular weight (Mn), and weight average molecular weight (Mw) of a binder resin constituting a polymerized toner according to one embodiment may be measured by GPC (Gel Permeation Chromatography). The peak molecular weight (Mp) of the binder resin may be 10,000 to 50,000, preferably 12,000 to 48,000, more preferably 15,000 to 45,000. The number average molecular weight (Mn) of the binder resin may be 10,000 to 50,000, preferably 12,000 to 48,000, more preferably 15,000 to 45,000. The weight average molecular weight (Mw) of the binder resin may be 10,000 to 150,000, preferably 20,000 to 120,000, more preferably 50,000 to 100,000. If the peak molecular weight (Mp), number average molecular weight (Mn) and weight average molecular weight (Mw) of the binder resin are respectively less than the lower limit in the above ranges, off set may be generated, and if they are respectively greater than the upper limit, glossiness may be lowered.

The ratio (Mn/Mp) of the number average molecular weight (Mn) to the peak molecular weight (Mp) of the binder resin may be 0.8 to 1.5, preferably 0.9 to 1.45, more preferably 1 to 1.4. If the ratio of the number average molecular weight/peak molecular weight (Mn/Mp) is less than 0.80, off set may be generated, and if is greater than 1.5, glossiness may be lowered. Particularly, when the ratio (Mn/Mp) of the number average molecular weight (Mn) to the peak molecular weight (Mp) of the binder resin in the polymerized toner is greater than 1, it means that the number of toner resins having smaller number average molecular weight than the peak molecular weight (Mp) is small, and when the ratio (Mn/Mp) of the number average molecular weight (Mn) to the peak molecular weight (Mp) is less than 1, it means that the number of toner resins having smaller number average molecular weight than the peak molecular weight (Mp) is large. Thus, as described below, the ratio of the number average molecular weight/peak molecular weight (Mn/Mp) may be optimized within the above explained range by using an appropriate amount of a chain transfer agent when preparing a polymerized toner.

In the polymerized toner of the present invention, the gel content (Gel %) of the binder resin may be measured by a soxlet method, and the Gel % of the binder resin may be 2% to 20%, preferably 3% to 15%, more preferably 5% to 10%. If the Gel % of the binder resin is less than 2%, off set may be generated, and if it is greater than 20%, glossiness may be lowered.

As explained above, the polymerized toner of the present invention may consist of toner particles comprising a binder resin, and a pigment, a charge control agent and wax, which are dispersed in the binder resin. Particularly, the peak molecular weight (Mp), the number average molecular weight (Mn), the weight average molecular weight (Mw), the ratio of number average molecular weight/peak molecular weight (Mn/Mp), and the Gel % of the binder resin in the polymerized toner of the present invention may be adjusted by using appropriate chain transfer agent and cross linking agent.

The monomer for a binder resin may include all monomers used in a toner prepared by polymerization without specific limitations. Specific examples of the monomer may include styrene monomer, acrylate monomer, methacrylate monomer, or diene monomer, and the like, and they may be used alone or in combination of two or more kinds. And, at least one of acidic olefin monomer or basic olefin monomer may be optionally mixed with the monomer.

The binder resin may include a polymer or a copolymer of styrene monomers, acrylate monomers, methacrylate monomers, diene monomers, acidic olefin monomers and basic olefin monomers, or a mixture thereof. However, various monomers known to be usable to form a toner prepared by suspension polymerization may be used without specific limitation, and a polymer or a copolymer that becomes a binder resin of a polymerized toner may be formed from the monomers.

And, the binder resin may include a polymer or a copolymer of (a) styrene monomer; and (b) at least one selected from the group consisting of acrylate monomer, methacrylate monomer and diene monomer. The polymer may include 30 to 95 parts by weight of the (a) monomers, and 5 to 70 parts by weight of the (b) monomers, based on 100 parts by weight of the sum of the (a) monomers and the (b) monomers.

The polymer may be a polymer of (a) styrene monomer, (b) at least one selected from the group consisting of acrylate monomer, methacrylate monomer and diene monomer, and (c) at least one selected from the group consisting of acidic olefin monomer and basic olefin monomer. The (c) monomers may be polymerized in the amount of 0.1 to 30 parts by weight, based on 100 parts by weight of the sum of the (a) monomers and the (b) monomers.

The styrene monomer for a binder resin may include styrene, monochlorostyrene, methyl styrene, dimethyl styrene, and the like, and the acrylate monomer may include methylacrylate, ethylacrylate, n-butylacrylate, isobutylacrylate, dodecyl acrylate, 2-ethylhexylacrylate, and the like. And, the methacrylate monomer may include methyl methacrylate, ethyl methacrylate, n-butyl methacrylate, isobutyl methacrylate, dodecyl methacrylate, 2-ethylhexyl methacrylate, and the like, and the diene monomer may include butadiene, isoprene, and the like.

And, as the acidic olefin monomer, an α,β-ethylene unsaturated compound having a carboxylic acid group, and the like may be used, and as the basic olefin monomer, methacrylate ester of aliphatic alcohol having an amine group or a quaternary ammonium group, methacryl amide, vinyl amine, diallyl amine or an ammonium salt thereof, and the like may be used.

Meanwhile, according to one embodiment of the invention, the toner particles may comprise a binder resin, and a pigment, a charge control agent, and wax, which are dispersed in the binder resin. And, the toner particles may comprise 50 to 95 wt %, preferably 60 to 93 wt %, more preferably 70 to 90 wt % of a binder resin; 1 to 20 wt %, preferably 2 to 15 wt %, more preferably 3 to 10 wt % of a pigment; 0.1 to 5 wt %, preferably 0.3 to 4 wt %, more preferably 0.5 to 3 wt % of a charge control agent; and 0.1 to 30 wt %, preferably 1 to 25 wt %, more preferably 5 to 20 wt % of wax. By maintaining the contents of the binder resin, and the pigment, charge control agent, and wax, dispersed in the binder resin within the above range, the polymerized toner may exhibit uniform image with excellent image density and excellent transfer efficiency, and simultaneously, effectively prevent offset phenomenon whereby a toner pollutes a fixing roll.

The pigment may include metal powder pigment, metal oxide pigment, carbon pigment, sulfide pigment, chromium salt pigment, ferrocyanide pigment, azo pigment, acid salt pigment, basic dye pigment, mordant dye pigment, phthalocyanine, quinacridone pigment, and dioxane pigment, and a mixture thereof. However, it is not limited thereto, and pigments known to be applicable in a polymerized toner may be used without specific limitation.

The polymerized toner of the present invention may further comprise a pigment stabilizer together with the pigment component, and the pigment stabilizer may be included in the content of 0.1 to 20 wt %, preferably 0.2 to 15 wt %, more preferably 0.3 to 10 wt %. As the pigment stabilizer, styrene-butadiene (SBS) copolymer having weight average molecular weight of 2,000 to 200,000 may be used, and preferably, the copolymer having a weight ratio of styrene and butadiene of 10:90 and 90:10 may be used. If the content of styrene is greater than 90%, the length of a butadiene block may be decreased, and thus, stabilizer function may not be sufficiently manifested due to high compatibility with a binder resin, and if it is less than 10%, although stabilizer function may be sufficiently manifested, pigment to pigment function may not be sufficiently controlled due to the short length of a styrene block. And, if the molecular weight is less than 2,000, it may not function as a pigment due to high compatibility with a binder resin, and if the molecular weight is greater than 200,000, the viscosity of a monomer mixture may be too increased to worsen dispersion stability and polymerization stability, and ultimately, widen particle size distribution. The charge control agent may include a cationic charge control agent, an anionic charge control agent, or a mixture thereof. The cationic charge control agent may include nigrosine-type dye, a metal salt of higher aliphatic compound, alkoxy amine, chelate, a quaternary ammonium salt, alkylamide, a fluorinated activator and a metal salt of naphthalenic acid, and a mixture thereof; and the anionic charge control agent may include chlorinated paraffin, chlorinated polyester, acid-containing polyester, sulfonyl amine of copper phthalocyanine, a sulfonic acid group, and a mixture thereof.

And, as the charge control agent, a copolymer having a sulfonic acid group is preferably used, and more preferably, a copolymer having a sulfonic acid group and having weight average molecular weight of 2,000 to 200,000 may be used, and still more preferably, a copolymer having a sulfonic acid group having an acid value of 1 to 40 mg KOH/g and glass transition temperature of 30 to 120° C. may be used. If the acid value is less than 1, it cannot perform a function as a charge control agent, and if the acid value is 40 or more, it may influence on the interfacial property of the monomer mixture to worsen polymerization stability. And, if the glass transition temperature is less than 30° C., friction-melting of toner may be generated when printing due to low glass transition temperature of the charge control agent that is exposed on the surface, thus inducing blocking, and if it is greater than 120° C., the surface of toner may become excessively hard and it is not preferable in terms of coatability and fixability. And, if the weight average molecular weight is less than 2,000, surface concentration may be lowered due to high compatibility with a binder resin and the function of a charge control agent may not be manifested, and if it is greater than 200,000, the viscosity of the monomer mixture may be increased due to high molecular weight, and it is not preferable in terms of polymerization stability and particle size distribution. Specific examples of the copolymer having a sulfonic acid group may include a styrene-acrylic copolymer having a sulfonic acid group, a styrene-methacrylic copolymer having a sulfonic acid group, and a mixture thereof, but not limited thereto.

As the wax, petroleum wax such as paraffin wax, microcrystalline wax, or ceresin wax, and the like; natural wax such as carnauba wax, and the like; or synthetic wax such as polyester wax or polyolefin wax such as polyethylene or polypropylene, and the like, or combinations thereof may be used.

Meanwhile, according to one embodiment of the invention, the toner particles may further comprise at least one additive selected from the group consisting of a reaction initiator, a cross linking agent, a molecular weight control agent, a lubricant (for example, oleic acid, stearic acid, and the like) and a coupling agent. The toner particles may further comprise 10 wt % or less, or 0.1 to 10 wt %, preferably 8 wt % or less, or 0.3 to 8 wt %, more preferably 5 wt % or less, or 0.5 to 5 wt % of the reaction initiator; 5 wt % or less, or 0.01 to 5 wt %, preferably 4 wt % or less, or 0.05 to 4 wt %, more preferably 3 wt % or less, or 0.1 to 3 wt % of the cross linking agent; 10 wt % or less, or 0.1 to 10 wt %, preferably 8 wt % or less, or 0.3 to 8 wt %, more preferably 5 wt % or less, or 0.5 to 5 wt % of the molecular weight control agent; appropriate amount of the lubricant (for example, oleic acid, stearic acid, and the like), for example, 5 wt % or less, or 0.01 to 5 wt %, preferably 4 wt % or less, or 0.05 to 4 wt %, more preferably 3 wt % or less, or 0.1 to 3 wt % of the lubricant; appropriate amount of the coupling agent, for example, 5 wt % or less, or 0.01 to 5 wt %, preferably 4 wt % or less, or 0.05 to 4 wt %, more preferably 3 wt % or less, or 0.1 to 3 wt % of the coupling agent, or combinations thereof.

As the reaction initiator, oil-soluble initiators and water-soluble initiators may be used. Specifically, azo initiators such as azobisisobutyronitrile, azobisvaleronitrile, and the like; organic peroxide such as benzoylperoxide, lauroylperoxide, and the like; commonly used water-soluble initiators such as potassium persulfate, ammonium persulfate, and the like may be used, and they may be used alone or in combinations of two or more kinds.

The cross linking agent may include divinylbenzen, ethylene dimethacrylate, ethyleneglycol dimethacrylate, diethyleneglycol diacrylate, 1,6-hexamethylene diacrylate, allyl methacrylate, 1,1,1-trimethylolpropane triacrylate, triallylamine, tetra allyloxy ethane, and a mixture thereof.

The molecular weight control agent may include t-dodecyl mercaptan, n-dodecyl mercaptan, n-octylmercaptan, carbon tetrachloride, and a mixture thereof.

As the lubricant and the coupling agent, those known to be applicable in the preparation of a polymerized toner may be used without specific limitation.

The polymerized toner of the present invention may comprise 50 to 95 wt % of a binder resin; 1 to 20 wt % of a pigment; 0.1 to 5 wt % of a charge control agent; 0.1 to 30 wt % of wax; and 10 wt % or less, or 0.01 to 10 wt % of at least one additive selected from the group consisting of a reaction initiator, a cross linking agent, a molecular weight control agent, a lubricant, and a coupling agent.

And, according to one embodiment, the toner particles may further comprise a coating layer containing external additives such as silica, titanium dioxide or a mixture thereof, and the like. The external additives may be coated on the outermost part of the toner particles. The silica may be preferably surface-treated with a silane compound such as dimethyldichlorosilane, dimethylpolysiloxane, hexamethyldisilazane, aminosilane, alkylsilane or octamethylcyclotetrasiloxane, and the like. As the titanium dioxide, rutile-type titanium dioxide that is stable at high temperature or anatase-type titanium dioxide that is stable at low temperature may be used alone or in combination, and those having particle size of 80 to 200 nm, preferably 100 to 150 nm may be used.

In the polymerized toner of the present invention, the toner particles may have average particle diameter of 4 to 10 μm, preferably 5 to 8 μm, more preferably 6 to 7 μm. The average particle diameter of the toner particles may be 4 μm or more in terms of image density and prevention of scattering, and it may be 10 μm or less so as to reduce consumption amount.

Meanwhile, according to another embodiment of the invention, a method for preparing the polymerized toner is provided. Particularly, the method for preparing a polymerized toner may comprise forming an aqueous dispersion comprising a dispersant; forming a monomer mixture comprising monomers for a binder resin, a pigment, a charge control agent, wax, a cross linking agent and a molecular weight control agent; and adding the monomer mixture to the aqueous dispersion to form toner particles through suspension polymerization.

The inventors confirmed that by adding optimum amounts of appropriate molecular weight agent and cross liking agent when preparing a toner by suspension polymerization, a polymerized toner wherein the peak molecular weight (Mp), the ratio of number average molecular weight/peak molecular weight (Mn/Mp), and the Gel % of a binder resin are optimized within specific ranges may be prepared, and that the prepared polymerized toner, when applied for printing, may improve glossiness and realize excellent off set property, and completed the invention. The polymerized toner may be effectively applied in the field of photograph printing and the like, which requires high resolution and color realization degree.

According to another embodiment of the invention, a dispersant may be mixed with water to form the aqueous dispersion. In order to homogenize the aqueous dispersion, a step of agitating or applying shearing stress may be applied. Specifically, the step of forming an aqueous dispersion may comprise mixing a sodium phosphate aqueous solution and a calcium chloride aqueous solution to obtain crystalline potassium phosphate in the aqueous solution phase. The potassium phosphate may be used as a dispersant, and the aqueous dispersion may include potassium phosphate crystals uniformly dispersed in water.

The dispersant may prevent aggregation of monomers for a binder resin or pigments and the like that exist as droplets between particles, and allows uniform dispersion of the particles. And, the dispersant may be uniformly adsorbed to the surface of droplets to stabilize the droplets. And, the dispersant may be solubilized in the aqueous medium by acid or alkali treatment, or hot water washing and the like, after a polymerization reaction is completed, and it may be separated from toner particles.

The dispersant includes an inorganic dispersant, an organic dispersant, an anionic surfactant or a mixture thereof. The dispersant may be applied in the amount of 1 to 5 parts by weight, preferably 2 to 4 parts by weight, more preferably 2.5 to 3.5 parts by weight, based on 100 parts by weight of the monomer mixture.

Specific examples of the inorganic dispersant may include calcium phosphate, calcium hydrogen phosphate, monocalcium phosphate, hydroxy apatite, magnesium phosphate, aluminum phosphate, zinc phosphate, calcium carbonate, magnesium carbonate, calcium hydroxide, magnesium hydroxide, aluminum hydroxide, calcium metasilicate, calcium sulfate, barium sulfate, bentonite, silica, alumina, or a mixture thereof, and the like.

Specific examples of the water-soluble organic dispersant may include polyvinyl alcohol, gelatin, methyl cellulose, methyl hydroxy propyl cellulose, ethyl cellulose, carboxyl methyl cellulose and a sodium salt thereof, polyacrylic acid and a salt thereof, starch, or a mixture thereof, and the like.

Specific examples of the anionic surfactant may include fatty acid salts, alkyl ester sulfate, alkylaryl ester sulfate, dialkyl sulfosuccinate, alkyl diphosphate, and a mixture thereof, and the like.

More preferable example of the dispersant may include calcium phosphate. The calcium phosphate may be obtained in the form of crystals in an aqueous solution phase by mixing a sodium phosphate aqueous solution and a calcium chloride aqueous solution, and the aqueous dispersion may include calcium phosphate crystals uniformly dispersed in water.

Meanwhile, the monomer mixture may be formed by mixing the monomers for a binder resin, a pigment, a charge control agent, wax, a crosslinking agent, and a molecular weight control agent, and the like, and sufficiently dissolving them, and it may be homogenized in the aqueous dispersion using a homogenizer.

The monomer for a binder resin may include styrene monomer, acrylate monomer, methacrylate monomer, diene monomer, acidic olefin monomer, basic olefin monomer, and a mixture thereof.

And, the monomer for a binder resin may comprise (a) styrene monomer; and (b) at least one selected from the group consisting of acrylate monomer, methacrylate monomer and diene monomer. The monomer for a binder resin may comprise 30 to 95 parts by weight of the (a) monomers and 5 to 70 parts by weight of the (b) monomers, based on 100 parts by weight of the sum of the (a) monomers and the (b) monomers.

And, the monomer for a binder resin may comprise (a) styrene monomer, (b) at least one selected from the group consisting of acrylate monomer, methacrylate monomer and diene monomer, and (c) at least one selected from the group consisting of acidic olefin monomer and basic olefin monomer. The (c) monomers may be included in the amount of 0.1 to 30 parts by weight, based on 100 parts by weight of the sum of the (a) monomers and the (b) monomers.

Meanwhile, specific examples of the monomer for a binder resin, the pigment, the charge control agent, the wax, the cross linking agent, and the molecular weight control agent are as explained above. And, the monomer mixture may comprise 50 to 95 wt % of the monomers for a binder resin, 1 to 20 wt % of the pigment, 0.1 to 5 wt % of the charge control agent, 0.1 to 30 wt % of the wax, 0.01 to 5 wt % of the cross linking agent, and 0.1 to 10 wt % of the molecular weight control agent.

Particularly, the contents of the cross linking agent and the molecular weight control agent may be controlled so that a polymerized toner of the present invention may be prepared with optimum ranges of peak molecular weight (Mp), ratio (Mn/Mp) of number average molecular weight (Mn) to the peak molecular weight (Mp), and Gel % of a binder resin, as explained above. In this regard, the cross linking agent may be used in the content of 0.01 to 5 wt %, preferably 0.1 to 4 wt %, more preferably 0.1 to 3 wt %. And, the molecular weight control agent may be used in the content of 0.1 to 10 wt %, preferably 0.3 to 8 wt %, more preferably 0.5 to 5 wt %.

Toner particles may be formed by mixing the monomer mixture in the aqueous dispersion and conducting suspension polymerization. More specifically, the step of forming the toner particles may comprise adding the monomer mixture to the aqueous dispersion; applying shearing stress to the aqueous dispersion and the monomer mixture to homogenize the monomer mixture in the aqueous dispersion in the form of droplets; and suspension-polymerizing the homogenized monomer mixture. And, as explained above, the monomer mixture and the aqueous dispersion may be homogenized using a homogenizer.

By dispersing the monomer mixture in the aqueous solution in the form of fine droplets and conducting polymerization, spherical toner particles with appropriate size may be formed. For the dispersion in the form of fine droplets, shearing stress may be applied to the monomer mixture and the aqueous dispersion to homogenize the mixture using a homogenizer, and specifically, the monomer mixture that is mixed with the aqueous dispersion may be homogenized at 5,000 rpm to 20,000 rpm, preferably 8,000 rpm to 17,000 rpm using a homogenizer, so as to disperse the monomer mixture in the aqueous dispersion in the form of droplets.

The suspension polymerization may be conducted at 60 to 90° C. for 8 to 20 hours. More preferably, after progressing the suspension polymerization reaction at 50 to 70° C. for 8 to 12 hours, temperature may be increased to 80 to 110° C., and then, the reaction may be progressed for 30 minutes to 4 hours, According to the suspension polymerization, a polymerized toner wherein the ratio of toner particles including 2 or more wax domains is 10% to 60% of total toner particles may be prepared, thus exhibiting high glossiness and transfer efficiency.

Meanwhile, according to another embodiment of the invention, the method for preparing a polymerized toner may further comprise removing the dispersant; and drying the toner particles.

The step of removing the dispersant may comprise controlling pH so as to be appropriate for dissolving the dispersant. By adding water-soluble inorganic acid such as hydrochloric acid or nitric acid, and the like, to the dispersion including produced toner particles so as to control the pH to 2 or less, preferably 1.5 or less, the dispersant may be dissolved in an aqueous solution phase and removed from the toner particles. In the step of removing the dispersant, pH is appropriately controlled, the solution is agitated for 5 hours or more so as to sufficiently dissolve the dispersant, and then, toner slurry containing less than 50 wt % of water may be obtained using a filter. And, in the step of removing the dispersant, application of shearing stress to homogenize the solution using a homogenizer, and separation with a centrifuge may be applied. And, after the above explained step of removing the dispersant, removing moisture using a filter and adding an excessive amount of distilled water may be repeated several times to more efficiently remove the dispersant.

The step of drying toner particles may comprise putting dispersant-removed toner cake in a vacuum oven and vacuum-drying at room temperature. However, any drying methods known to be commonly used in the preparation of a polymerized toner may be used without specific limitations.

And, according to one embodiment of the invention, the method for preparing a polymerized toner may further comprise coating the outside of the toner particles. In the coating step, separate external additives, for example, inorganic powder containing silica, titanium dioxide or a mixture thereof, and the like may be coated on the surface of toner particles, and the coating of external additives may be progressed by adding the external additives to the toner particles and then agitating at high speed using an henschel mixer. As the silica, those known to be usable in a polymerized toner may be used without specific limitation. Inoragnic powder that can be applied in the coating step is as explained above, and the detailed explanations thereof are omitted.

And, the method may further comprise adding at least one additive selected from the group consisting of a reaction initiator, a lubricant, and a coupling agent to the monomer mixture. Specific examples and preferable contents of the additives are as explained above.

Meanwhile, the polymerized toner of the present invention may have narrow particle diameter distribution and high image density and realize uniform image with excellent transfer efficiency, and particularly, the gloss unit may be 27 or more, preferably 30 or more in a printed paper, and the afterimages existing in the form of a spot within 1 cm length and 1 cm width may be less than 20, preferably less than 10.

Other details may be adjusted as necessary, and are not specifically limited in the present invention.

### Advantageous Effects

According to the present invention, by optimizing peak molecular weight (Mp), ratio of number average molecular weight/peak molecular weight (Mn/Mp), gel content (Gel %) of a binder resin constituting a polymerized toner within specific ranges, a polymerized toner that may realize high glossiness and excellent off set property when applied for printing, and a method for preparing the same are provided.

Particularly, the polymerized toner of the present invention may improve glossiness and minimize off set generation, and it may exhibit very excellent performance in the application field such as development of electronic photographs and the like.

### DESCRIPTION OF DRAWINGS

FIG. 1 schematically shows a fixing roll that is used for measuring off set property of the polymerized toner of the present invention.

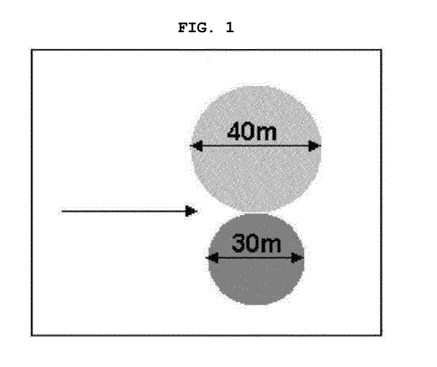

### MODE FOR INVENTION

Hereinafter, preferable examples are presented to aid in understanding of the present invention, however, these examples are only to illustrate the invention and the scope of the invention is not limited thereto.

### Example 1

### Preparation of a Polymerized Toner

686 g of a 0.1 M sodium phosphate aqueous solution and 100 g of 1M calcium chloride were mixed in 500 g of water, and agitated at a reaction temperature of 70° C. for 20 minutes to prepare an aqueous dispersion including precipitated calcium phosphate crystals. In the aqueous dispersion, the content of calcium phosphate crystals was adjusted to 3 parts by weight, based on 100 parts by weight of a monomer mixture described below.

160 g of styrene, 36 g of n-butyl acrylate, and 4 g of acrylic acid as monomers for a binder resin, 2 g of allyl methacrylate (AMA) as a cross linking agent, 2 g of n-dodecylmercaptan (NDDM) as a molecular weight control agent, and 2 g of styrene-acrylic-based polymer including a sulfonic acid group and having weight average molecular weight of 16,000 as a charge control agent were mixed and sufficiently dissolved, 10 g of carbon black was added thereto, the mixture was agitated in a bead meal of 2,000 rpm for 2 hours, and then, the bead was removed to finally prepare 225 g of a mixture of the monomers and the pigment.

The temperature of the bead-removed mixture was increased to 70° C. in a water bath, 20 g of paraffin wax (Fisher) was further added, the mixture was agitated to completely dissolve the wax in the mixture, and the mixture was additionally agitated for 5 minutes to prepare a monomer mixture. The weight of the monomer mixture was 245 g.

And, a mixed solution of 5 g of an azo nitrile initiator (Azo nitrile, V65, Wako Co. Ltd.) 10 g of styrene, and 5 g of n-butyl acrylate was added to the monomer mixture, and the monomer mixture was added to the aqueous dispersion. And then, shearing stress was applied at 13,000 rpm using a homogenizer to disperse and homogenize the monomer mixture in the aqueous solution in the form of droplets. The monomer mixture dispersed in the aqueous solution in the form of fine droplets through the homogenization was reacted at 60° C. for 10 hours while agitating at 200 rpm with a paddle-type agitator, the temperature was increased to 90° C., and the mixture was additionally reacted for 3 hours to prepare a polymerized toner.

Washing and Drying of Toner Particles

Hydrochloric acid was added to the slurry including a polymerized toner to control the pH to 2 or less, and calcium phosphate was dissolved therein. And, water was removed using a filter, distilled water was added in the amount of 2 times of total weight to dilute the slurry, shearing stress was applied to homogenize it using a homogenizer, and then, centrifugation was conducted at 3,000 rpm for 15 minutes using a centrifugal device (Beckman J2-21M, Rotor JA-14). The process of dilution, homogenization and centrifugation was repeated three times to remove calcium phosphate and other impurities on the surface of toner.

Finally, moisture was removed through filtering, and then, the toner cake was put in a vacuum oven and vacuum-dried at room temperature for 48 hours to prepare a polymerized toner core. The volume average particle diameter of the prepared polymerized toner core was 7 μm, and the ratio of volume average particle diameter and number average particle diameter (standard deviation) was 1.26. The volume average particle diameter of the core was measured using a Coulter counter (Multisizer 3, Beckman coulter).

Coating of External Additives

2 parts by weight of silica was mixed with 100 parts by weight of the polymerized toner core using a henshcel mixer. Then, it was agitated at high speed of 5,000 rpm for 7 minutes to coat external additives on the surface of the polymerized toner core.

### Example 2

A polymerized toner was prepared by the same method as Example 1, except using 3 g of AMA (allyl methacrylate).

### Example 3

A polymerized toner was prepared by the same method as Example 1, except using 1.5 g of n-dodecyl mercaptan (NDDM).

### Example 4

A polymerized toner was prepared by the same method as Example 1, except using 1.5 g of n-dodecyl mercaptan (NDDM) and 1 g of allyl methacrylate (AMA).

### Example 5

A polymerized toner was prepared by the same method as Example 1, except using 1.5 g of n-dodecyl mercaptan (NDDM) and 4 g of allyl methacrylate (AMA).

### Example 6

A polymerized toner was prepared by the same method as Example 1, except using 1.5 g of n-dodecyl mercaptan (NDDM) and 0.9 g of allyl methacrylate (AMA).

### Example 7

A polymerized toner was prepared by the same method as Example 1, except using 1.5 g of n-dodecyl mercaptan (NDDM) and 3.8 g of allyl methacrylate (AMA).

### Example 8

A polymerized toner was prepared by the same method as Example 1, except using 2 g of n-dodecyl mercaptan (NDDM) and 0.5 g of allyl methacrylate (AMA).

### Example 9

A polymerized toner was prepared by the same method as Example 1, except using 3 g of n-dodecyl mercaptan (NDDM) and 2 g of allyl methacrylate (AMA).

### Comparative Example 1

A polymerized toner was prepared by the same method as Example 1, except that allyl methacrylate (AMA) and t-dodecyl mercaptan (TDDM) were not used.

### Comparative Example 2

A polymerized toner was prepared by the same method as Example 1, except that 2 g of t-dodecyl mercaptan (TDDM) was used and allyl methacrylate (AMA) was not added.

### Comparative Example 3

A polymerized toner was prepared by the same method as Example 1, except that t-dodecyl mercaptan (TDDM) was not added and 2 g of allyl methacrylate (AMA) was used.

### Comparative Example 4

A polymerized toner was prepared by the same method as Example 1, except that 4 g of t-dodecyl mercaptan (TDDM) was used and allyl methacrylate (AMA) was not added.

### Comparative Example 5

A polymerized toner was prepared by the same method as Example 1, except that 1.5 g of t-dodecyl mercaptan (TDDM) and 5 g of allyl methacrylate (AMA) were used.

### Comparative Example 6

A polymerized toner was prepared by the same method as Example 1, except that 3 g of t-dodecyl mercaptan (TDDM) and 0.2 g of allyl methacrylate (AMA) were used.

### Comparative Example 7

A polymerized toner was prepared by the same method as Example 1, except that 1 g of t-dodecyl mercaptan (TDDM) and 3 g of allyl methacrylate (AMA) were used.

### Comparative Example 8

A polymerized toner was prepared by the same method as Example 1, except that 1.5 g of t-dodecyl mercaptan (TDDM) and 0.5 g of allyl methacrylate (AMA) were used.

### Comparative Example 9

A polymerized toner was prepared by the same method as Example 1, except that 1.5 g of t-dodecyl mercaptan (TDDM) and 10 g of allyl methacrylate (AMA) were used.

Specific contents, namely, added amount (g) of the cross linking agent (AMA) and the molecular weight control agent (NDDM, TDDM) and the wt % to the monomer mixture in Examples 1 to 9 and Comparative Examples 1 to 9 are as shown in the following Table 1.

TABLE 1

| | |
|---|---|
| Contents of molecular | Contents of cross |
| weight control agent | linking agent |

| | Added | | Added | |
|---|---|---|---|---|
| | amount (g) | wt % | amount (g) | wt % |
| Example 1 | 2 | 0.816 | 2 | 0.816 |
| Example 2 | 2 | 0.816 | 3 | 1.224 |
| Example 3 | 1.5 | 0.612 | 2 | 0.816 |
| Example 4 | 1.5 | 0.612 | 1 | 0.408 |
| Example 5 | 1.5 | 0.612 | 4 | 1.633 |
| Example 6 | 1.5 | 0.612 | 0.9 | 0.367 |
| Example 7 | 1.5 | 0.612 | 3.8 | 1.551 |
| Example 8 | 2 | 0.816 | 0.5 | 0.204 |
| Example 9 | 3 | 1.224 | 2 | 0.816 |
| Comparative | — | — | — | — |
| Example 1 | | | | |
| Comparative | 2 | 0.816 | — | — |
| Example 2 | | | | |
| Comparative | — | — | 2 | 0.816 |
| Example 3 | | | | |
| Comparative | 4 | 1.633 | — | — |
| Example 4 | | | | |
| Comparative | 1.5 | 0.612 | 5 | 2.041 |
| Example 5 | | | | |
| Comparative | 3 | 1.224 | 0.2 | 0.082 |
| Example 6 | | | | |
| Comparative | 1 | 0.408 | 3 | 1.224 |
| Example 7 | | | | |
| Comparative | 1.5 | 0.612 | 0.5 | 0.204 |
| Example 8 | | | | |
| Comparative | 1.5 | 0.612 | 10 | 4.082 |
| Example 9 | | | | |

### Experimental Example

For the polymerized toners prepared according to Examples 1 to 9 and Comparative Examples 1 to 9, physical properties were measured as follows.

Measurement of Molecular Weight

The molecular weights, Mp, Mw, Mn of the binder resin constituting a polymerized toner were measured using Gel Permeation Chromatography (GPC).

Measurement of Gel Content (Gel %)

The gel content (Gel %) of the binder resin constituting a polymerized toner was measured by a soxhlet method.

Measurement of Glossiness

After printing on the front side of a A4 paper using a laser printer (CP1215, Manufacturer: Hewlett Packard), the gloss units of 4 edge parts and 1 center part of the printed paper were measured using a gloss meter (Mcbath) and the average values was taken.

Measurement of Offset Property

After printing an image of width 1 cm and length 5 cm 5 times at an interval of 5 cm on a A4 paper, it was observed whether or not after image remains on the paper at an interval of 5.7 cm interval that is a circumference of a fixing roll from the rectangular printed product to evaluate off set property.

The degree of after image was observed by a microscope. And, if the number of spots is 20 or more in the after image existing in the form of spot within 1 cm length and 1 cm width, off set property was evaluated as being faulty; if the number is 10-20, it was evaluated as being normal, and if the number is less than 10, it was evaluated as being good.

The measurement values of the molecular weights (Mn, Mp, Mw) and the Gel % of the binder resin in the polymerized toners prepared according to Examples 1 to 9 and Comparative Examples 1 to 9, and the evaluation results of gloss units and off set properties of the polymerized toners are as shown in the following Table 2.

TABLE 2

| | Mn | Mp | Mw | Mn/Mp | Gel % | Gloss unit | Offset property |
|---|---|---|---|---|---|---|---|
| Example 1 | 15,000 | 15,000 | 80,000 | 1 | 10 | 35 | good |
| Example 2 | 20,000 | 16,000 | 85,000 | 1.25 | 15 | 32 | good |
| Example 3 | 20,400 | 17,000 | 9,000 | 1.2 | 12 | 33 | good |
| Example 4 | 10,000 | 11,000 | 60,000 | 0.9 | 8 | 35 | good |
| Example 5 | 50,000 | 60,000 | 90,000 | 0.83 | 20 | 33 | good |
| Example 6 | 10,000 | 10,000 | 50,000 | 1 | 7 | 38 | good |
| Example 7 | 50,000 | 50,000 | 80,000 | 1 | 18 | 35 | good |
| Example 8 | 9,000 | 9,000 | 40,000 | 1 | 5 | 37 | good |
| Example 9 | 15,000 | 10,000 | 80,000 | 1.5 | 10 | 35 | good |
| Comparative | 50,000 | 60,000 | 150,000 | 0.83 | — | 25 | good |
| Example 1 | | | | | | | |
| Comparative | 20,000 | 40,000 | 70,000 | 0.5 | — | 35 | faulty |
| Example 2 | | | | | | | |
| Comparative | 20,000 | 60,000 | 170,000 | 3 | 20 | 20 | good |
| Example 3 | | | | | | | |
| Comparative | 8,000 | 9,000 | 40,000 | 0.88 | 1 | 37 | faulty |
| Example 4 | | | | | | | |
| Comparative | 52,000 | 60,000 | 122,000 | 0.87 | 22 | 20 | good |
| Example 5 | | | | | | | |
| Comparative | 15,000 | 25,000 | 110,000 | 0.6 | 3 | 36 | faulty |
| Example 6 | | | | | | | |
| Comparative | 19,800 | 11,000 | 90,000 | 1.8 | 17 | 22 | good |
| Example 7 | | | | | | | |
| Comparative | 10,000 | 10,000 | 60,000 | 1.0 | 3.5 | 35 | faulty |
| Example 8 | | | | | | | |
| Comparative | 15,000 | 15,000 | 80,000 | 1 | 22 | 20 | good |
| Example 9 | | | | | | | |

As shown in the Table 2, it was confirmed that the polymerized toners of Examples 1 to 9 wherein the Mp, the ratio of Mn/Mp, the Gel % of the toner resin are optimized in specific ranges may exhibit high glossiness and good off set property. In general, the gloss unit of a printed product measured by a contact type gloss meter such as RD918 (Macbeth Company) should be 28 or more so as to realize very similar color to general photographs and high printing quality. If the polymerized toners of Examples 1 to 9 are applied, high gloss unit of 32 or more may be realized, and good off set property may be exhibited. Thus, the polymerized toners of Examples 1 to 9 may be applied in the field of development of electronic photographs and the like, which requires high printing quality.

Meanwhile, as shown in the Table 2, in the case of Comparative Examples 1, 3 and 5 wherein the Mp of the toner resin is too large as 60,000, the gloss units are just 25, 20 and 20, respectively. To the contrary, it can be seen that in the case of Comparative Example 4 wherein the Mp of the toner resin is just 9,000, off set property is not good. And, it can be seen that in the case of Comparative Examples 3 and 7 wherein the ratios Mn/Mp of the toner resin are too large as 3 and 1.8, respectively, the gloss units are just 20 and 22, respectively. Also, in the case of Comparative Examples 2 and 6 wherein the ratios Mn/Mp of the toner resin are too small as 0.5 and 0.6, respectively, faulty off set property is exhibited. Meanwhile, it can be seen that in the case of Comparative Examples 5 and 9 wherein the Gel % of the toner resin measured by a soxhelt method is too high as 22%, the gloss unit is just 20. Also, in the case of Comparative Examples 1 to 2 and 4, 6, 8 wherein the Gel % of the toner resin is not measured or is too low as 1%, 3% and 3.5%, respectively, faulty off set property is exhibited. Therefore, the polymerized toners of Comparative Examples 1 to 9 wherein the molecular weight properties and the gel content (Gel %) of the binder resin are not simultaneously optimized cannot be applied for development of electronic photographs which require high glossiness and excellent off set property.

1. A polymerized toner comprising
a binder resin, and
a pigment, a charge control agent, and wax, which are dispersed in the binder resin,
wherein the binder resin has peak molecular weight (Mp) of 10,000 to 50,000, the ratio of number average molecular weight (Mn) to peak molecular weight (Mp) is 0.8 to 1.5, and gel content (Gel %) measured by a soxhlet method is 5% to 20%.

2. The polymerized toner according to claim 1, wherein the binder resin includes a polymer of at least one selected from the group consisting of styrene monomer, acrylate monomer, methacrylate monomer, diene monomer, acidic olefin monomer, and basic olefin monomer.

3. The polymerized toner according to claim 1, wherein the binder resin includes a polymer of (a) styrene monomer; and (b) at least one selected from the group consisting of acrylate monomer, methacrylate monomer, and diene monomer.

4. The polymerized toner according to claim 1, wherein the binder resin includes a polymer of the (a) styrene monomer, (b) at least one selected from the group consisting of acrylate monomer, methacrylate monomer and diene monomers, and (c) at least one selected from the group consisting of acidic olefin monomer and basic olefin monomer.

5. The polymerized toner according to claim 1, wherein the binder resin has number average molecular weight (Mn) of 10,000 to 50,000.

6. The polymerized toner according to claim 1, wherein the binder resin has weight average molecular weight (Mw) of 50,000 to 120,000.

7. The polymerized toner according to claim 1, wherein the wax includes at least one selected from the group consisting of paraffin wax, microcrystalline wax, ceresin wax, carnauba wax, polyester wax, and polyolefin wax.

8. The polymerized toner according to claim 1, wherein the charge control agent includes at least one cationic charge control agent selected from the group consisting of nigrosine-type dye, a metal salt of higher aliphatic compound, alkoxy amine, chelate, a quaternary ammonium salt, alkylamide, a fluorinated activator, and a metal salt of naphthalenic acid; or at least one anionic charge control agent selected from the group consisting of chlorinated paraffin, chlorinated polyester, acid-containing polyester, sulfonyl amine of copper phthalocyanine, and styrene-acrylic-based polymer containing a sulfonic acid group.

9. The polymerized toner according to claim 1, wherein the pigment includes at least one selected from the group consisting of metal powder type pigment, metal oxide type pigment, carbon type pigment, sulfide type pigment, chromium type pigment, ferrocyanide type pigment, azo type pigment, acid salt type pigment, basic dye type pigment, mordant dye type pigment, phthalocyanine, quinacridone type pigment, and dioxane type pigment.

10. The polymerized toner according to claim 1, wherein the polymerized toner comprises 50 to 95 wt % of a binder resin, 1 to 20 wt % of a pigment, 0.1 to 5 wt % of a charge control agent, and 0.1 to 30 wt % of wax.

11. The polymerized toner according to claim 1, wherein the toner particles further comprises at least one additives selected from the group consisting of a reaction initiator, a cross linking agent, a molecular weight control agent, a lubricant, and a coupling agent.

12. The polymerized toner according to claim 11, wherein the polymerized toner comprises 50 to 95 wt % of a binder resin; 1 to 20 wt % of a pigment; 0.1 to 5 wt % of a charge control agent; 0.1 to 30 wt % of wax; and 10 wt % or less of at least one additives selected from the group consisting of a reaction initiator, a cross linking agent, a molecular weight control agent, a lubricant, and a coupling agent.

13. A method for preparing the polymerized toner according to claim 1 comprising
forming an aqueous dispersion comprising a dispersant;
forming a monomer mixture comprising monomers for a binder resin, a pigment, a charge control agent, wax, a cross linking agent and a molecular weight control agent; and
adding the monomer mixture to the aqueous dispersion to form toner particles through suspension polymerization.

14. The method according to claim 13, wherein the dispersant includes at least one selected from the group consisting of an inorganic dispersant, a water-soluble organic polymer dispersant, and an anionic surfactant.

15. The method according to claim 13, wherein the monomer mixture further comprises at least one additive selected from the group consisting of a reaction initiator, a lubricant, and a coupling agent.

16. The method according to claim 13, wherein the step of forming toner particles comprises adding the monomer mixture to the aqueous dispersion; applying shearing stress to the aqueous dispersion and the monomer mixture to homogenize the monomer mixture in the aqueous dispersion in the form of droplets; and suspension-polymerizing the homogenized monomer mixture.
